(19) United States
(12) Patent Application Publication
(10) Pub. No.: US 2025/0318205 A1
(43) Pub. Date: Oct. 9, 2025

(54) FERROELECTRIC THIN FILM TRANSISTOR AND METHOD OF OPERATING THE SAME

(71) Applicant: POSTECH RESEARCH AND BUSINESS DEVELOPMENT FOUNDATION, Pohang-si (KR)

(72) Inventors: Jang Sik LEE, Pohang-si (KR); Ik Jyae KIM, Pohang-si (KR)

(21) Appl. No.: 19/170,195

(22) Filed: Apr. 4, 2025

(30) Foreign Application Priority Data
Apr. 4, 2024 (KR) 10-2024-0045845

(51) Int. Cl. H10D 30/69; H10D 30/67

(52) U.S. Cl. CPC H10D 30/701; H10D 30/6737; H10D 30/6755; H10D 30/6757

(57) ABSTRACT

The present disclosure relates to a ferroelectric thin film transistor and may include: a substrate; a gate electrode layer formed on the substrate; a ferroelectric layer formed on the gate electrode layer, including a hafnium-based oxide, and including an uneven portion having at least one or more step that is formed on the gate electrode layer; a semiconductor channel layer formed on the ferroelectric layer and including an oxide semiconductor; a drain electrode layer connected to the semiconductor channel layer at one side of the gate electrode layer; and a source electrode layer connected to the semiconductor channel layer at the other side of the gate electrode layer.

### CROSS-REFERENCE TO RELATED APPLICATIONS

This application claims priority from Korean Patent Application No. 10-2024-0045845 filed on Apr. 4, 2024, in the Korean Intellectual Property Office, and all the benefits accruing therefrom under 35 U.S.C. 119, the contents of which in its entirety are herein incorporated by reference.

### TECHNICAL FIELD

The present disclosure relates to a semiconductor device and more specifically to a ferroelectric thin film transistor and an operating method thereof. The present disclosure relates to the Development of Next-generation Intelligent Semiconductor Technology Project (Project No. 00258227, Detailed Project No. 1711196855) which was carried out with the support of the National Research Foundation of Korea and the funds of the Ministry of Science and ICT.

### BACKGROUND

Recently, a hafnia (HfO₂)-based material is being used as one of materials for a ferroelectric thin film transistor. The hafnia-based ferroelectric material is known to have advantages such as compatibility with a complementary metal oxide semiconductor process depending on a dopant material and concentration thereof, high expandability, low power consumption, and high operation speed. Due to these advantages, the hafnia-based ferroelectric material is being utilized for next-generation memory and logic devices.

However, a hafnia-based ferroelectric thin film transistor has a memory window smaller than that of a conventional memory device such as a charge trap flash memory, and thus there was a problem that it was difficult to implement multi-level characteristics.

In order to expand the memory window of such ferroelectric thin film transistor, a coercive field or a thickness of a ferroelectric layer should be increased. However, it is difficult to obtain ferroelectricity in a thick film, and it is necessary to develop a film with a high coercive field rather than increasing the thickness. The coercive field of the ferroelectric layer is typically in a range of 1 to 2 MV/cm, depending on a dopant element and concentration. For this reason, it is necessary to develop a method capable of stably controlling the multi-level characteristics in addition to expanding the memory window.

In order to increase reliability of a multi-level operation, it is essential to consider a threshold voltage distribution in an intermediate state. However, when a voltage pulse with an amplitude close to the coercive field is applied to the ferroelectric thin film transistor, the threshold voltage changes abruptly. Due to such an abrupt polarization switching characteristic, it is necessary to finely adjust a voltage pulse amplitude or width in order to implement the multi-level characteristics.

### SUMMARY

### Technical Problem

The present disclosure is designed to solve various problems including the above-mentioned problems and is directed to providing of a structure of a ferroelectric thin film transistor capable of effectively controlling multi-level characteristics and an operating method thereof. However, these problems are exemplary and the scope of the present disclosure is not limited thereto.

### Technical Solution

A ferroelectric thin film transistor according to an aspect of the present disclosure for solving the above problem may include: a substrate; a gate electrode layer formed on the substrate; a ferroelectric layer formed on the gate electrode layer, including a hafnium-based oxide, and including an uneven portion having one or more steps such that a thickness thereof is variables across the ferroelectric layer; a semiconductor channel layer formed on the ferroelectric layer and including an oxide semiconductor; a drain electrode layer connected to the semiconductor channel layer at one side of the gate electrode layer; and a source electrode layer connected to the semiconductor channel layer at the other side of the gate electrode layer.

According to an embodiment of the present disclosure, the uneven portion may be formed at a portion where the ferroelectric layer and the semiconductor channel layer are in contact with each other.

According to an embodiment of the present disclosure, the uneven portion may include at least two steps.

According to an embodiment of the present disclosure, the uneven portion may be a groove portion, and the steps may be gradually formed such that a center region of the ferroelectric layer has the thinnest thickness.

According to an embodiment of the present disclosure, the uneven portion may be a protruding portion, and the steps may be gradually formed such that the center region of the ferroelectric layer has the thickest thickness.

According to an embodiment of the present disclosure, the uneven portion may be formed to have at least three or more or seven or more steps.

According to an embodiment of the present disclosure, the ferroelectric layer may include hafnium oxide to which at least one of zirconium (Zr), aluminum (Al), silicon (Si), yttrium (Y), gadolinium (Gd), and lanthanum (La) is added.

According to an embodiment of the present disclosure, the semiconductor channel layer may include an n-type oxide semiconductor or a p-type oxide semiconductor, the n-type oxide semiconductor may include at least one of indium oxide (InOx), zinc oxide (ZnOx), indium tin oxide (InSnOx), indium zinc oxide (InZnOx), indium gallium oxide (InGaOx), zinc tin oxide (ZnSnOx), aluminum zinc oxide (AlZnOx), indium gallium zinc oxide (InGaZnOx), gallium zinc oxide (GaZnOx), indium zinc tin oxide (InZnSnOx), and hafnium indium zinc oxide (HfInZnOx), and the p-type oxide semiconductor may include at least one of copper oxide (CuOx), nickel oxide (NiOx), tin oxide (SnOx), manganese oxide (MnOx), copper aluminum oxide (CuAlOx), copper gallium oxide (CuGaOx), and copper chromium oxide (CuCrOx).

According to an embodiment of the present disclosure, the gate electrode layer, the drain electrode layer, and the source electrode layer may include a metal or a transparent conductive oxide.

According to an embodiment of the present disclosure, the transparent conductive oxide may include at least one of indium oxide (InOx), zinc oxide (ZnOx), indium tin oxide (InSnOx), indium zinc oxide (InZnOx), indium gallium oxide (InGaOx), zinc tin oxide (ZnSnOx), aluminum zinc oxide (AlZnOx), indium gallium zinc oxide (InGaZnOx), gallium zinc oxide (GaZnOx), indium zinc tin oxide (InZnSnOx), hafnium indium zinc oxide (HfInZnOx), copper oxide (CuOx), nickel oxide (NiOx), tin oxide (SnOx), manganese oxide (MnOx), copper aluminum oxide (CuAlOx), copper gallium oxide (CuGaOx), and copper chromium oxide (CuCrOx).

According to an embodiment of the present disclosure, the gate electrode layer, the drain electrode layer, and the source electrode layer may include a metal or a metal nitride.

According to an embodiment of the present disclosure, the drain electrode layer and the source electrode layer may be formed to be spaced apart from each other on the ferroelectric layer, one side of the semiconductor channel layer may extend from the ferroelectric layer to an end portion of the drain electrode layer, and the other side of the semiconductor channel layer may extend from the ferroelectric layer to an end portion of the source electrode layer.

A multi-level operating method of a ferroelectric thin film transistor according to another aspect of the present disclosure for solving the above problem may include a ferroelectric layer formed on a gate electrode layer, an uneven portion having at least one or more step that is formed in a part so that a thickness thereof is variable, and a semiconductor channel layer, the method includes:

analyzing a change in a threshold voltage (Vₜₕ) of the device according to a pulse amplitude and a pulse width by applying a program voltage to the gate electrode layer with a different pulse amplitude in order to control a polarization level of the ferroelectric layer as multi-level; and controlling the multi-level operation of the device by confirming a region where the threshold voltage decreases and a region where the threshold voltage is maintained constant and selecting the pulse amplitude and the pulse width in the region where the threshold voltage is maintained constant.

According to an embodiment of the present disclosure, erasing of applying an erase voltage to the gate electrode layer may be performed before the analyzing of the change in the threshold voltage.

According to an embodiment of the present disclosure, the region where the threshold voltage is maintained constant may be formed according to a structure of the uneven portion provided in the ferroelectric layer.

### Advantageous Effects

According to a ferroelectric thin film transistor and an operating method thereof according to an embodiment of the present disclosure as described above, multi-level characteristics can be effectively controlled, and operation performance and operation reliability can be improved. Of course, the scope of the present disclosure is not limited by these effects.

### BRIEF DESCRIPTION OF THE DRAWINGS

FIG. 1 is a schematic cross-sectional view showing a ferroelectric thin film transistor according to an embodiment of the present disclosure.

FIG. 2 is a schematic cross-sectional view showing a ferroelectric thin film transistor according to another embodiment of the present disclosure.

FIG. 3 is a graph showing polarization characteristics according to a voltage applied to a ferroelectric thin film having the same uneven portion as that utilized in a ferroelectric transistor 100 shown in FIG. 1.

FIG. 4 is a graph showing transfer characteristics of the ferroelectric transistor 100 shown in FIG. 1.

FIG. 5 is a graph showing a program and erase characteristics according to a pulse width of the ferroelectric transistor 100 shown in FIG. 1.

FIG. 6 is a flowchart showing a multi-level operating method of a ferroelectric transistor according to some embodiments of the present disclosure.

FIG. 7 is a view schematically showing an operation mechanism of the ferroelectric transistor 100 shown in FIG. 1.

FIG. 8 is a graph showing multi-level characteristics of a ferroelectric transistor measured by Experimental Example (grooved) of the present disclosure and Comparative Example (flat).

FIG. 9 is a schematic cross-sectional view showing a ferroelectric thin film transistor according to Comparative Example.

FIG. 10 is a graph showing transfer characteristics of the ferroelectric transistor shown in FIG. 9.

FIG. 11 is a graph showing a program and erase characteristics according to a pulse width of the ferroelectric transistor shown in FIG. 9.

### DETAILED DESCRIPTION OF THE EMBODIMENTS

Hereinafter, various preferred embodiments of the present disclosure will be described in detail with reference to the attached drawings.

Various embodiments of the present disclosure may be embodied in many different forms and should not be construed as being limited to the embodiments set forth herein. Rather, these embodiments of the disclosure are provided so that this disclosure will be thorough and complete and will convey inventive concepts of the disclosure to those skilled in the art. Also, in the drawings, the thicknesses or sizes of layers are exaggerated for clarity.

Embodiments of the disclosure are described herein with reference to schematic drawings of idealized embodiments of the disclosure. In the drawings, for example, according to the manufacturing technology and/or tolerance, variations from the shown shape may be expected. Thus, the embodiments of the disclosure should not be construed as limited to the particular shapes of regions shown herein, but are to include deviations in shapes that result, for example, from manufacturing.

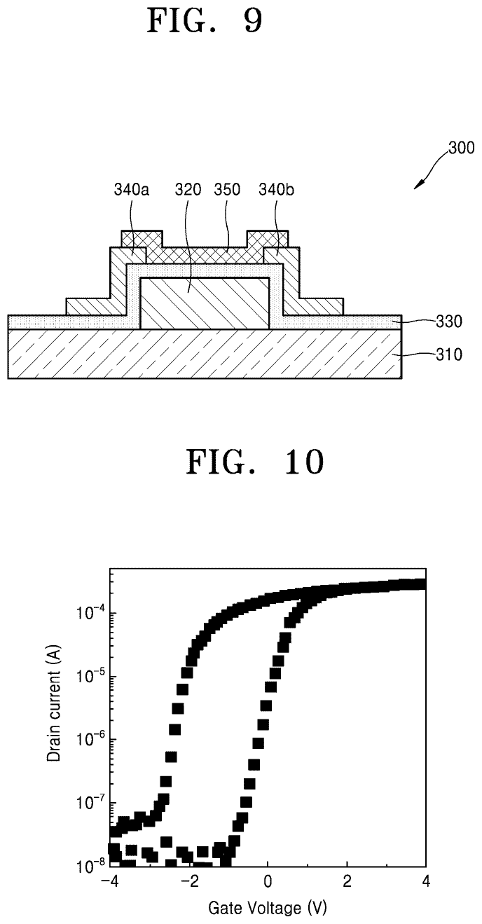

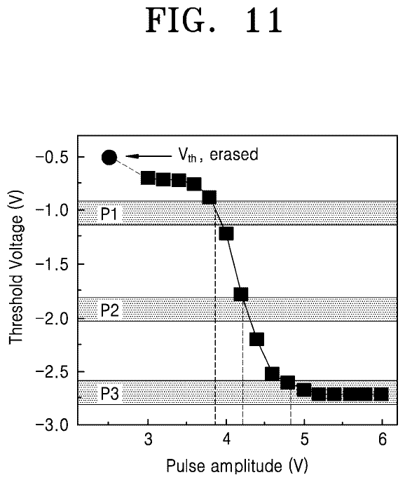

FIG. 9 is a schematic cross-sectional view showing a ferroelectric thin film transistor according to Comparative Example of the present disclosure, FIG. 10 is a graph showing transfer characteristics of the ferroelectric transistor shown in FIG. 9, and FIG. 11 is a graph showing a program and erase characteristics according to a pulse width of the ferroelectric transistor shown in FIG. 9.

Referring to FIGS. 9 to 11, a ferroelectric transistor 300 according to Comparative Example of the present disclosure includes a substrate 310, a gate electrode layer 320, a ferroelectric layer 330, a semiconductor channel layer 350, a drain electrode layer 340a, and a source electrode layer 340b. As a result of measuring a drain current while sweeping a gate voltage in a range of −4 V to 4 V, the ferroelectric transistor 300 showed an n-type transfer characteristic having an anticlockwise hysteresis as shown in FIG. 10.

In order to implement multi-level characteristics of the ferroelectric transistor 300, in the related art, a threshold voltage corresponding to a multi-level is selected within a range in which there is no interference between respective states after confirming a change in the threshold voltage (V) according to a pulse width as shown in FIG. 11. A necessary voltage is applied to secure the threshold voltage selected as such.

However, in the ferroelectric transistor 300, a rapid polarization switching occurs near a coercive field. As a result, the change in the threshold voltage (V) of the ferroelectric transistor 300 shows a rapid change at a specific voltage by polarization. Accordingly, a very precise voltage adjustment is required when implementing the multi-level characteristics of the ferroelectric transistor 300. In addition, there is a problem that a range of each state increases.

In order to solve this problem, the present disclosure attempts to effectively select a program voltage by forming a ferroelectric layer having a structure with different steps. Hereinafter, a ferroelectric transistor according to an embodiment of the present disclosure will be described in detail with reference to the drawings.

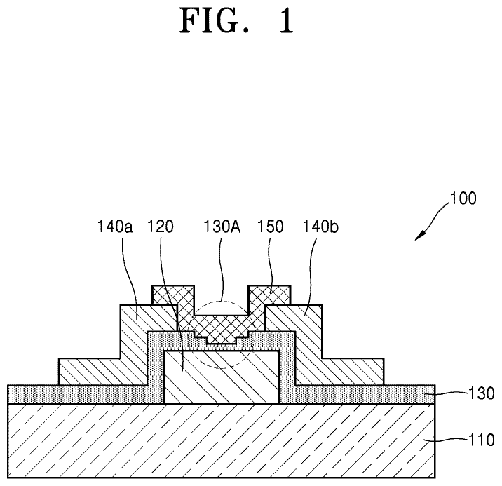

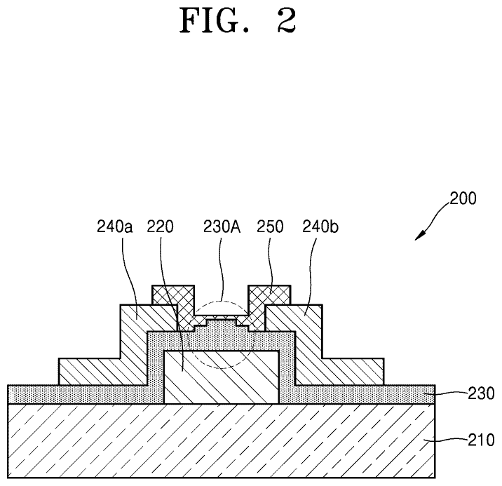

FIG. 1 is a schematic cross-sectional view showing a ferroelectric thin film transistor according to an embodiment of the present disclosure, and FIG. 2 is a schematic cross-sectional view showing a ferroelectric thin film transistor according to another embodiment of the present disclosure.

Referring to FIG. 1, a ferroelectric transistor 100 may include a substrate 110, a gate electrode layer 120, a ferroelectric layer 130, a semiconductor channel layer 150, a drain electrode layer 140a, and a source electrode layer 140b.

For example, the ferroelectric transistor 100 may have a structure of a field effect transistor (FET), and in this case, it may be called a ferroelectric FET (FeFET). Further, the ferroelectric transistor 100 may operate as a non-volatile memory device that stores data in the ferroelectric layer 130, and in this case, it may be called a ferroelectric memory device. However, such a ferroelectric memory device may be distinguished from a memory device composed of the ferroelectric transistor and a capacitor in that it does not require a separate capacitor.

Various materials may be used for the substrate 110, for example, when configuring a transparent device, the substrate 110 may include a transparent substrate. For example, when the ferroelectric transistor 100 is utilized as a display device, the substrate 110 may be composed of silicon (Si), silicon dioxide (SiO₂), or a glass substrate. Likewise, the ferroelectric transistor 100 may also be called a ferroelectric thin film transistor (FeTFT) in that it is formed in a thin film structure.

The gate electrode layer 120 may be formed on the substrate 110. For example, the gate electrode layer 120 may be formed to have a predetermined pattern on the substrate 110. The ferroelectric layer 130 may be formed on the gate electrode layer 120. The semiconductor channel layer 150 may be formed on the ferroelectric layer 130. The drain electrode layer 140a and the source electrode layer 140b may be connected to the semiconductor channel layer 150 at both sides of the gate electrode layer 120, respectively.

More specifically, the ferroelectric layer 130 may be formed on the substrate 110 to cover the gate electrode layer 120. The ferroelectric layer 130 may include a layer capable of storing data by using a polarization phenomenon. The ferroelectric layer 130 may include a high dielectric material such as a hafnium-based oxide. The ferroelectric layer 130 may include a hafnium oxide to which at least one of zirconium (Zr), aluminum (Al), silicon (Si), yttrium (Y), gadolinium (Gd), and lanthanum (La) is added. In addition, for example, the ferroelectric layer 130 may include a hafnium-zirconium oxide (HZO), such as HfZrOx. In some embodiments, the ferroelectric layer 130 may include a mixed structure or a stacked structure of the hafnium oxide (HfO₂) and zirconium oxide (ZrO₂). In some embodiments, the ferroelectric layer 130 is formed and heat treated at a temperature of 280° C., thereby exhibiting ferroelectric characteristics with only a low-temperature process.

A part of the ferroelectric layer 130 may include an uneven portion 130a in which one or more step is formed. In the uneven portion 130a, a thickness of the ferroelectric layer 130 may be varied across the ferroelectric layer 130. For example, the uneven portion 130a may include at least two or more steps. By configuring the thickness of the ferroelectric layer into a multi-stage step structure by the uneven portion 130a, multi-stage characteristics are induced to the threshold voltage in the ferroelectric transistor 100, enabling window enlargement during a multi-level operation.

For example, for a multi-level operation control (MLC) of the ferroelectric transistor 100, the uneven portion 130a may include at least three or more steps. In addition, for a triple-level operation control (TLC) of the ferroelectric transistor 100, the uneven portion 130a may include at least seven or more steps.

The uneven portion 130a may be formed at a portion where the ferroelectric layer 130 and the semiconductor channel layer 150 are in contact with each other. As an example, the uneven portion 130a may be a groove portion, and steps may be gradually formed such that a center region of the ferroelectric layer 130 has the thinnest thickness.

For example, the uneven portion 130a having three steps (groove portions) may be formed by a two-step etching process. After forming the ferroelectric layer 130 on the gate electrode layer 120 using an atomic layer deposition method, a part of the ferroelectric layer 130 may be partially removed using a wet etching method. In this case, a first groove portion is formed so that the ferroelectric layer 130 is not penetrated. A part of the ferroelectric layer 130 corresponding to a region relatively narrower than a region of the first groove portion may be partially removed by the same method to form a second groove portion in a region relatively deeper and narrower than the first groove portion. The first groove portion and the second groove portion may be formed in a left-right symmetrical form based on a center of the ferroelectric layer 130.

As another example, as shown in FIG. 2, an uneven portion 230A formed in a ferroelectric transistor 200 may have an upwardly protruding form. An uneven portion 230A is a protruding portion, and steps may be gradually formed such that a center region of the ferroelectric layer 230 has the thickest thickness.

For example, the uneven portion 230A having three steps (protruding portions) may be formed by a two-step deposition process. After forming the ferroelectric layer 230 on a gate electrode layer 220 using the atomic layer deposition method, a first protruding portion is formed on an area relatively narrower than an entire surface area of the ferroelectric layer 230 using the same deposition method. Thereafter, a second protruding portion may be formed on a region relatively narrower than an area of the first protruding portion using the same method. The first protruding portion and the second protruding portion may be formed in a left-right symmetrical form based on a center of the ferroelectric layer 230.

Referring again to FIG. 1, the semiconductor channel layer 150 may be formed on the ferroelectric layer 130 to at least partially correspond to the gate electrode layer 120. The semiconductor channel layer 150 may have a structure interlocked with the structure of the uneven portion 130a depending on the form of the uneven portion 130a of the ferroelectric layer 130.

The semiconductor channel layer 130 may include an n-type oxide semiconductor or a p-type oxide semiconductor. For example, an n-type material may include at least one of indium oxide (InOx), zinc oxide (ZnOx), indium tin oxide (InSnOx), indium zinc oxide (InZnOx), indium gallium oxide (InGaOx), zinc tin oxide (ZnSnOx), aluminum zinc oxide (AlZnOx), indium gallium zinc oxide (InGaZnOx), gallium zinc oxide (GaZnOx), indium zinc tin oxide (InZnSnOx), and hafnium indium zinc oxide (HfInZnOx), and a p-type material may include at least one of copper oxide (CuOx), nickel oxide (NiOx), tin oxide (SnOx), manganese oxide (MnOx), copper aluminum oxide (CuAlOx), copper gallium oxide (CuGaOx), and copper chromium oxide (CuCrOx).

The drain electrode layer 140a and the source electrode layer 140b may be formed to be spaced apart from each other on the ferroelectric layer 130. For example, the drain electrode layer 140a may be connected to the semiconductor channel layer 150 at one side of the gate electrode layer 120, and the source electrode layer 140b may be connected to the semiconductor channel layer 150 at the other side of the gate electrode layer 120.

In some embodiments, one side of the semiconductor channel layer 150 may extend from the ferroelectric layer 130 to an end portion of the drain electrode layer 140a, and the other side of the semiconductor channel layer 150 may extend from the ferroelectric layer 130 to an end portion of the source electrode layer 140b. For example, the drain electrode layer 140a may extend from the ferroelectric layer 130 on the substrate 110 outside of the gate electrode layer 120 to the ferroelectric layer 130 on one side of the gate electrode layer 120, and the source electrode layer 140b may extend from the ferroelectric layer 130 on the substrate 110 outside of the gate electrode layer 120 to the ferroelectric layer 130 on the other side of the gate electrode layer 120.

The gate electrode layer 120, the drain electrode layer 140a, and the source electrode layer 140b may be formed of a suitable conductive material. For example, the gate electrode layer 120 may include a transparent conductive oxide. The transparent conductive oxide may include at least one of indium oxide (InOx), zinc oxide (ZnOx), indium tin oxide (InSnOx), indium zinc oxide (InZnOx), indium gallium oxide (InGaOx), zinc tin oxide (ZnSnOx), aluminum zinc oxide (AlZnOx), indium gallium zinc oxide (InGaZnOx), gallium zinc oxide (GaZnOx), indium zinc tin oxide (InZnSnOx), hafnium indium zinc oxide (HfInZnOx), copper oxide (CuOx), nickel oxide (NiOx), tin oxide (SnOx), manganese oxide (MnOx), copper aluminum oxide (CuAlOx), copper gallium oxide (CuGaOx), and copper chromium oxide (CuCrOx).

In some embodiments, since the gate electrode layer 120, the drain electrode layer 140a, and the source electrode layer 140b occupy a relatively small area in the device, when implementing an alternative transparent device, it is not limited to a transparent material and may include a metal or a metal nitride. For example, the gate electrode layer 120, the drain electrode layer 140a, and the source electrode layer 140b may include a thin film of one of Cu, Al, Ti, W, Mo, Pt, Au, Ni, and TiN, or a stacked structure of two or more thereof.

In some embodiments, when the gate electrode layer 120, the drain electrode layer 140a, and the source electrode layer 140b are formed of a transparent conductive oxide, such as indium tin oxide (ITO), the ferroelectric transistor 100 may be entirely transparent in a visible light region.

In the ferroelectric transistor 100 of some embodiments, the ferroelectric layer 130 may be formed of a hafnium-zirconium oxide (HZO), the semiconductor channel layer 150 may be formed of an indium-zirconium oxide (IZO), the gate electrode layer 120 may be formed of tungsten (W), and the drain electrode layer 140a and the source electrode layer 140b may be formed of molybdenum (Mo).

Hereinafter, electrical characteristics of the ferroelectric transistor 100 will be described.

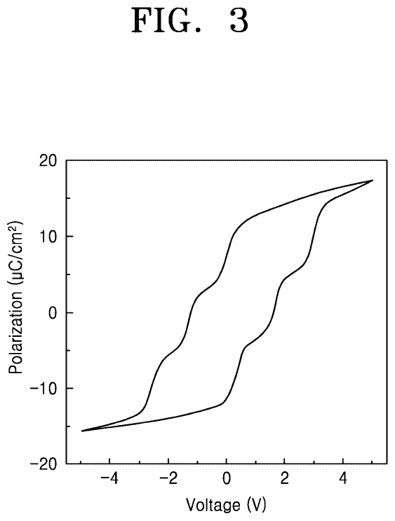

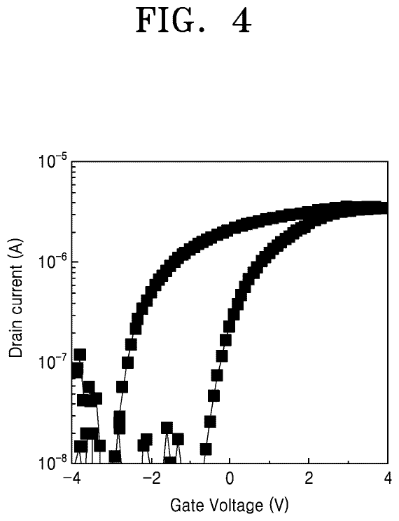

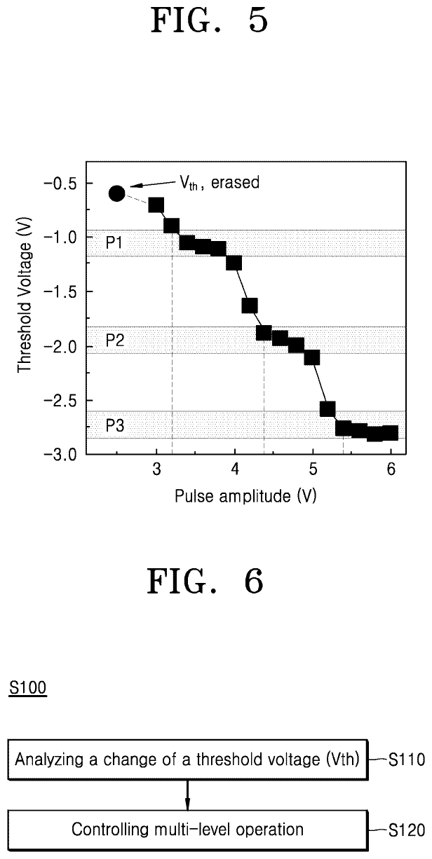

FIG. 3 is a graph showing polarization characteristics according to a voltage applied to a ferroelectric thin film having the same uneven portion as that utilized in the ferroelectric transistor 100 shown in FIG. 1, FIG. 4 is a graph showing transfer characteristics of the ferroelectric transistor 100 shown in FIG. 1, and FIG. 5 is a graph showing a program and erase characteristics according to a pulse width of the ferroelectric transistor 100 shown in FIG. 1.

Referring to FIG. 3, as a result of measuring the polarization characteristics while sweeping a gate voltage in a range of −4 V to 4 V, it was confirmed that three regions with polarization switching were identified. The three regions were identified in a range of 0.5 to 1 V, 1.5 to 2 V, and 2.5 to 3 V.

In a case of the ferroelectric transistor 100 including the uneven portion 130a, it was confirmed that it was easy to secure a plurality of switching voltages because polarization switching occurs near the coercive field, unlike the ferroelectric transistor (300 in FIG. 9) according to Comparative Example of the present disclosure.

Referring to FIG. 4, as a result of measuring the polarization characteristics while sweeping the gate voltage in the range of −4 V to 4 V, the ferroelectric transistor 100 showed an n-type transfer characteristic having an anticlockwise hysteresis. From this, the ferroelectric characteristics of the hafnium-based oxide, for example, the ferroelectric layer 130 composed of HZO, may be confirmed.

Referring to FIG. 5, as a result of measuring a threshold voltage (Vₜₕ) while applying a program voltage to the ferroelectric transistor 100 with a fixed pulse width of 1 us, a change in the threshold voltage (a section where a plurality of the threshold voltage (Vₜₕ) changes or are constant) was observed in a window wider than the ferroelectric transistor (300 in FIG. 9) according to Comparative Example of the present disclosure when the ferroelectric layer 130 including the uneven portion 130a was used. At this time, the ferroelectric transistor 100 was erased using a voltage pulse (−6 V, 100 us) before the program voltage was applied.

Hereinafter, an operating method of the above-described ferroelectric transistor 100, 200 will be described in more detail.

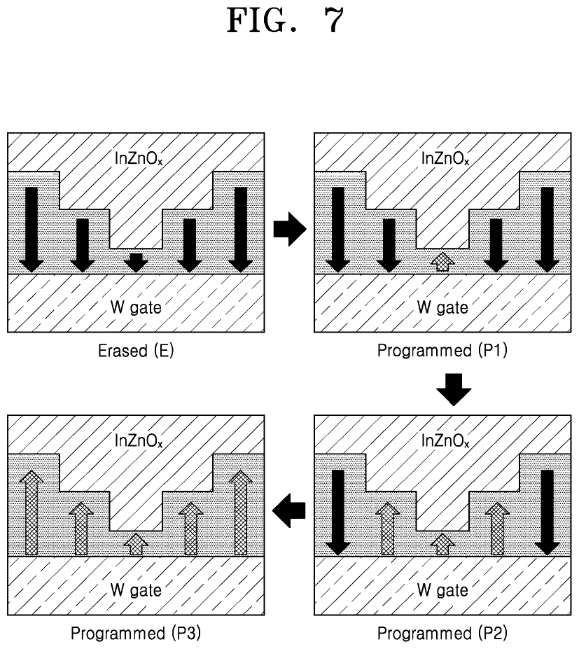

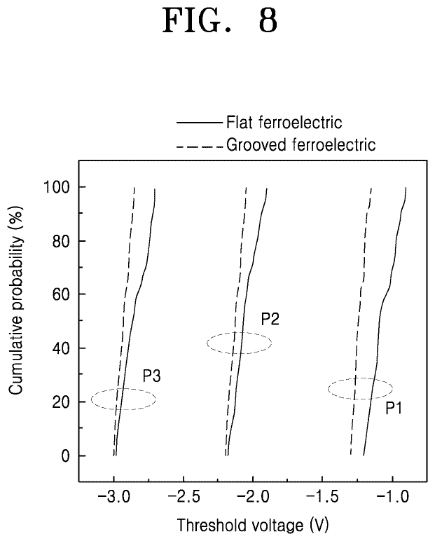

FIG. 6 is a flowchart showing a multi-level operating method of a ferroelectric transistor according to some embodiments of the present disclosure, FIG. 7 is a view schematically showing an operation mechanism of the ferroelectric transistor 100 shown in FIG. 1, and FIG. 8 is a graph showing multi-level characteristics of a ferroelectric transistor measured by Experimental Example (grooved) of the present disclosure and Comparative Example (flat).

Referring to FIG. 6, an operating method (S100) of the ferroelectric transistor 100 of the present disclosure may perform analyzing a change in the threshold voltage (Vₜₕ) (S110) and controlling a multi-level operation (S120). For example, the analyzing of the change in the threshold voltage (Vₜₕ) of the device 100 according to a pulse amplitude and a pulse width by applying a program voltage to the gate electrode layer 120 with a different pulse amplitude may be performed in order to control a polarization level of the ferroelectric layer 130 as multi-level. Thereafter, the controlling of the multi-level operation of the device 100 (S120) may be performed by confirming a region where the threshold voltage decreases and a region where the threshold voltage is maintained constant and selecting the pulse amplitude and the pulse width in the region where the threshold voltage is maintained constant.

Here, erasing of applying an erase voltage to the gate electrode layer 120 may be performed before the analyzing of the change in the threshold voltage (S110).

In addition, the region where the threshold voltage is maintained constant is formed according to a structure of the uneven portion 130a provided in the ferroelectric layer 130. When a section in which the threshold voltage is maintained constant according to the pulse amplitude is selected, the change in the threshold voltage is suppressed, thereby reducing a region that changes in each state.

Referring to FIG. 7, in a case of the ferroelectric transistor 100 including the ferroelectric layer 130 including the uneven portion 130a, a voltage amplitude window may be expanded by the uneven portion 130a, and such a window expansion may exhibit a significant difference compared to the program voltage required for each state of the ferroelectric transistor 300 having a flat ferroelectric layer 330. As shown in FIG. 7, level control in each state is easy depending on the applied program voltage, thereby leading to reliable multi-level characteristic control.

Referring to FIG. 8, voltage pulses with amplitudes of 3.8, 4.2, and 5 V were used in the flat ferroelectric transistor (300 in FIG. 9). On the other hand, in a case of the ferroelectric transistor 100 according to Example of the present disclosure, voltage pulses with amplitudes of 3, 4.5, and 5.5 V were used.

Although a distinguishable threshold voltage distribution was observed in the ferroelectric transistor according to Comparative Example and Example of the present disclosure, it was confirmed that the ferroelectric transistor 100 according to Example of the present disclosure had a narrower threshold voltage distribution. According to such a result, the ferroelectric transistor 100 according to Example of the present disclosure may lead to reliable multi-level characteristics, and the multi-level operation using many states, such as TLC or QLC operations may also be controlled depending on the structure and shape of the uneven portion 130a.

The present disclosure has been described with reference to the embodiments shown in the drawings, but these embodiments are merely illustrative and it should be understood by a person with ordinary skill in the art that various modifications and equivalent embodiments can be made without departing from the scope of the present disclosure. Therefore, the true technical protective scope of the present disclosure should be determined based on the technical concept of the appended claims.

What is claimed is:

1. A ferroelectric thin film transistor comprising:
a substrate;
a gate electrode layer formed on the substrate;
a ferroelectric layer formed on the gate electrode layer, including a hafnium-based oxide, and including an uneven portion having one or more steps formed such that a thickness thereof varies across the ferroelectric layer;
a semiconductor channel layer formed on the ferroelectric layer and including an oxide semiconductor;
a drain electrode layer connected to the semiconductor channel layer at one side of the gate electrode layer; and
a source electrode layer connected to the semiconductor channel layer at the other side of the gate electrode layer.

2. The ferroelectric thin film transistor of claim 1,
wherein the uneven portion is formed at a portion where the ferroelectric layer and the semiconductor channel layer are in contact with each other.

3. The ferroelectric thin film transistor of claim 1,
wherein the uneven portion includes at least two steps.

4. The ferroelectric thin film transistor of claim 3,
wherein the uneven portion is a groove portion, and the steps are gradually formed such that a center region of the ferroelectric layer has the thinnest thickness.

5. The ferroelectric thin film transistor of claim 3,
wherein the uneven portion is a protruding portion, and the steps are gradually formed such that a center region of the ferroelectric layer has the thickest thickness.

6. The ferroelectric thin film transistor of claim 1,
wherein the ferroelectric layer includes hafnium oxide to which at least one of zirconium (Zr), aluminum (Al), silicon (Si), yttrium (Y), gadolinium (Gd), and lanthanum (La) is added.

7. The ferroelectric thin film transistor of claim 1,
wherein the semiconductor channel layer includes an n-type oxide semiconductor or a p-type oxide semiconductor,
the n-type oxide semiconductor includes at least one of indium oxide (InOx), zinc oxide (ZnOx), indium tin oxide (InSnOx), indium zinc oxide (InZnOx), indium gallium oxide (InGaOx), zinc tin oxide (ZnSnOx), aluminum zinc oxide (AlZnOx), indium gallium zinc oxide (InGaZnOx), gallium zinc oxide (GaZnOx), indium zinc tin oxide (InZnSnOx), and hafnium indium zinc oxide (HfInZnOx), and
the p-type oxide semiconductor includes at least one of copper oxide (CuOx), nickel oxide (NiOx), tin oxide (SnOx), manganese oxide (MnOx), copper aluminum oxide (CuAlOx), copper gallium oxide (CuGaOx), and copper chromium oxide (CuCrOx).

8. The ferroelectric thin film transistor of claim 1,
wherein the gate electrode layer, the drain electrode layer, and the source electrode layer include a metal or a transparent conductive oxide.

9. The ferroelectric thin film transistor of claim 8,
wherein the transparent conductive oxide includes at least one of indium oxide (InOx), zinc oxide (ZnOx), indium tin oxide (InSnOx), indium zinc oxide (InZnOx), indium gallium oxide (InGaOx), zinc tin oxide (ZnSnOx), aluminum zinc oxide (AlZnOx), indium gallium zinc oxide (InGaZnOx), gallium zinc oxide (GaZnOx), indium zinc tin oxide (InZnSnOx), hafnium indium zinc oxide (HfInZnOx), copper oxide (CuOx), nickel oxide (NiOx), tin oxide (SnOx), manganese oxide (MnOx), copper aluminum oxide (CuAlOx), copper gallium oxide (CuGaOx), and copper chromium oxide (CuCrOx).

10. The ferroelectric thin film transistor of claim 1,
wherein the gate electrode layer, the drain electrode layer, and the source electrode layer include a metal or a metal nitride.

11. The ferroelectric thin film transistor of claim 1,
wherein the drain electrode layer and the source electrode layer are formed to be spaced apart from each other on the ferroelectric layer,
one side of the semiconductor channel layer extends from the ferroelectric layer to an end portion of the drain electrode layer, and the other side of the semiconductor channel layer extends from the ferroelectric layer to an end portion of the source electrode layer.

12. A multi-level operating method of a ferroelectric thin film transistor including a ferroelectric layer formed on a gate electrode layer, an uneven portion having at least one or more step formed on the gate electrode layer, and a semiconductor channel layer, the method comprising:
analyzing a change in a threshold voltage (Vₜₕ) of the device according to a pulse amplitude and a pulse width by applying a program voltage to the gate electrode layer with a different pulse amplitude in order to control a polarization level of the ferroelectric layer as multi-level; and
controlling multi-level operation of the device by confirming a region where the threshold voltage decreases and a region where the threshold voltage is maintained constant and selecting the pulse amplitude and the pulse width in the region where the threshold voltage is maintained constant.

13. The method of claim 12,
erasing of applying an erase voltage to the gate electrode layer is performed before the analyzing of the change in the threshold voltage.

14. The method of claim 12,
wherein the region where the threshold voltage is maintained constant is formed according to a structure of the uneven portion provided in the ferroelectric layer.

15. The method of claim 12,
wherein the uneven portion includes at least two steps.
